(19) United States
(12) Patent Application Publication
(10) Pub. No.: US 2026/0309160 A1
(43) Pub. Date: Oct. 8, 2026

(54) MANUFACTURING AUTOMATION SYSTEM, APPARATUS AND METHOD FOR CONTROLLING PROCESS ENVIRONMENT

(71) Applicant: Samsung Display Co., LTD., Yongin-si (KR)

(72) Inventors: Sung Su BAE, Yongin-si (KR); Byeong Han KIM, Yongin-si (KR); Jong Keun KIM, Yongin-si (KR); Tae Kyun NA, Yongin-si (KR); Hyun Hoo SEO, Yongin-si (KR); Chae Ho KIM, Yongin-si (KR); Jae Ik BAE, Yongin-si (KR); Hak Joo SHIN, Yongin-si (KR); Heung Won LEE, Yongin-si (KR)

(21) Appl. No.: 19/462,406

(22) Filed: Jan. 28, 2026

(30) Foreign Application Priority Data
Mar. 11, 2025 (KR) 10-2025-0031400

(51) Int. Cl. F04D 27/00; G05B 13/02

(52) U.S. Cl. CPC F04D 27/004; G05B 13/0265

(57) ABSTRACT

A manufacturing automation system includes: a cassette loaded with at least one target object and including at least one fan; a transport device, which transfers the cassette; a stocker, which stores the cassette transferred by the transport device, or moves the cassette to one of a plurality of pieces of process equipment, and includes a fan controller, which controls an operation speed of the at least one fan; a data collection device, which collects process information related to the cassette; and a control device, which receives the collected process information, generates fan control information for variably controlling the operation speed of the at least one fan based on the received process information, and transmits the generated fan control information to the fan controller of the stocker.

### RELATED APPLCATION

This application claims priority to Korean Patent Application No. 10-2025-0031400, filed on Mar. 11, 2025, and all the benefits accruing therefrom under 35 U.S.C. §119, the content of which in its entirety is herein incorporated by reference.

### TECHINICAL FIELD

Various embodiments of the present disclosure relate to a manufacturing automation system, as well as an apparatus and a method for controlling a process environment.

### BACKGROUND

Various electronic devices, such as smartphones, digital cameras, notebook computers, navigation systems, and smart televisions, include a display device. The display device may include a liquid crystal display (LCD), a field emission display (FED), an organic light-emitting display (OLED) and the like.

The display device may be manufactured through multiple processes, such as a substrate fabrication process, a cell fabrication process, and a module process. As such, the manufacturing processes of the display device, which consist of multiple steps, can be automated. For example, a target object (e.g., a substrate) that has completed processing by process equipment may be loaded into a loading device (e.g., a cassette), and then moved to another process equipment by a transport device (e.g., an automatic guided vehicle (AGV)). Meanwhile, the loading device may be stored in a storage device (e.g., a stocker).

Meanwhile, contamination may occur in the target object for various reasons during the manufacturing process. For example, the target object may be contaminated due to particles or foreign substances penetrating the inside of the loading device as a result of surrounding air current generated while being transferred to another process equipment after completion of the process or while being moved from a storage device to another storage device, potentially causing defects. As another example, a silver (Ag) dissolution defect may occur when stagnant for a certain period of time in a specific process. In addition, as another example, a defect may occur due to contamination of the manufacturing line, resulting in contamination of the target object. Further, as another example, a defect may occur in which the target object is corroded and/or rusted due to fumes generated in a specific process.

In order to prevent the contamination, the wind generated by fans located on the side and/or ceiling of the loading device is utilized to block particles or foreign substances from entering the inside of the loading device. However, the current automated system operates (e.g., rotates) the fans at a constant speed regardless of the characteristics of the process. As a result, the current automated system has a problem in that particles or foreign substances are not completely removed in some processes, or the fan is unnecessarily operated even in processes with a low risk of contamination, thereby increasing power consumption.

### SUMMARY

An aspect of various embodiments of the present disclosure is to provide a manufacturing automation system capable of improving the quality and manufacturing efficiency of a target object by adaptively (or variably) adjusting the operation time and/or operation intensity of an environmental control device depending on characteristics of the process, as well as an apparatus and a method for controlling a process environment.

Another aspect of various embodiments of the present disclosure is to provide a manufacturing automation system capable of reducing power consumption of an automation system by adaptively (or variably) adjusting the operation time and/or operation intensity of an environmental control device depending on characteristics of the process, as well as an apparatus and a method for controlling a process environment.

A manufacturing automation system according to an aspect of the present disclosure includes: a cassette loaded with at least one target object and including at least one fan; a transport device configured to transfer the cassette; a stocker which is configured to store the cassette transferred by the transport device, or move the cassette to one of a plurality of pieces of process equipment, and includes a fan controller configured to control an operation speed of the at least one fan; a data collection device configured to collect process information related to the cassette; and a control device configured to: receive the collected process information, generate fan control information for variably controlling the operation speed of the at least one fan based on the received process information, and transmit the generated fan control information to the fan controller of the stocker.

According to an embodiment, the control device may be configured to: analyze the process information to recognize a process step in which the cassette is located, determine a fan speed mapped to the recognized process step using a pre-stored mapping information database (DB), and generate the fan control information based on the determined fan speed.

According to an embodiment, the mapping information DB may include a mapping table in which process groups classified depending on characteristics of the process are mapped to fan speeds to be applied to corresponding process groups, respectively.

According to an embodiment, the mapping information DB may store a mapping between recipes of the process equipment and corresponding fan speeds, respectively.

According to an embodiment, the mapping information DB may store a mapping between lot information of the at least one target object and corresponding fan speeds.

According to an embodiment, when the cassette is provided in plurality, the control device may generate the fan control information by mapping identification information for each cassette to a fan speed to be applied to the at least one fan of a corresponding cassette.

According to an embodiment, the data collection device may include: a process data collection module configured to collect data related to a process step in which the cassette is located; a location data collection module configured to collect data related to a location of the cassette; and a quality data collection module configured to collect data related to quality of the at least one target object.

According to an embodiment, wherein the data collection device may include an artificial intelligence-based classification model which is pre-trained using training data to generate the process information based on raw data collected by at least one of the process data collection module, the location data collection module, and the quality data collection module.

According to an embodiment, the control device may include an artificial intelligence-based generation model which is pre-trained using training data to analyze the process information, and generate the fan control information based on the analyzed process information.

According to an embodiment, the at least one fan and the fan controller may communicate to each other via wireless communication.

According to an embodiment, the manufacturing automation system may further include a buffer unit located between the transport device and the stocker, and configured to temporarily store the cassette.

A method for controlling a process environment of a control device according to another aspect of the present disclosure includes: collecting process information related to a cassette loaded with at least one target object; analyzing the collected process information, generating fan control information for variably controlling an operation speed of at least one fan included in the cassette based on analysis results for the collected process information; and transmitting the generated fan control information to a fan controller configured to control an operation of the at least one fan.

According to an embodiment, the generating of the fan control information may include: analyzing the process information to recognize a process step in which the cassette is located; determining a fan speed mapped to the recognized process step using pre-stored mapping information; and generating the fan control information based on the determined fan speed.

According to an embodiment, the cassette is provided in plurality, and the generating of the fan control information may include, when a plurality of cassettes are stored in each stocker, generating the fan control information by mapping identification information for each cassette to a fan speed to be applied to the at least one fan of a corresponding cassette.

According to an embodiment, the collecting of the process information may include: a process data collection step of collecting data related to a process step in which the cassette is located; a position data collection step of collecting data related to a location of the cassette; and a quality data collection step of collecting data related to quality of the at least one target object.

In addition, am electronic device according to another aspect of the present disclosure may include: a communication module configured to receive process information related to a cassette loaded with at least one target object; and a control module configured to analyze the received process information, generate fan control information for variably controlling an operation speed of at least one fan included in the cassette based on analysis results for the received process information, and control the communication module to transmit the generated fan control information to a fan controller configured to control an operation of the at least one fan.

According to an embodiment, the electronic device may further include a memory configured to store a mapping information database (DB) in which process groups classified depending on characteristics of the process are mapped to fan speeds to be applied to corresponding process groups.

According to an embodiment, the electronic module may be configured to: analyze the process information to recognize a process step in which the cassette is located, determine a fan speed mapped to the recognized process step using the mapping information DB, and generate the fan control information based on the determined fan speed.

According to an embodiment, the mapping information DB may store a mapping between recipes of the process equipment and corresponding fan speeds, or a mapping between lot information of the at least one target object and corresponding fan speeds.

According to an embodiment, the cassette is provided in plurality, and when a plurality of cassettes are stored in the stocker, the control module may generate the fan control information by mapping identification information for each cassette to a fan speed to be applied to the at least one fan of a corresponding cassette.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a view schematically illustrating a manufacturing automation system according to an embodiment of the present disclosure;

FIG. 2A is a view illustrating the shape of a cassette according to an embodiment of the present disclosure;

FIG. 2B is a view for describing an example of varying the speed of a fan according to a process according to an embodiment of the present disclosure;

FIG. 3 is a flowchart describing a method for controlling a process environment of a manufacturing automation system according to an embodiment of the present disclosure;

FIG. 4 is a block diagram illustrating the configuration of an electronic device according to an embodiment of the present disclosure; and

FIG. 5 is a flowchart describing a method for controlling a process environment of an electronic device according to an embodiment of the present disclosure.

### DETAILED DESCRIPTION

Hereinafter, various embodiments of the present disclosure will be described with reference to the accompanying drawings. Specific embodiments of the present disclosure will be illustrated in the drawings and described in the following detailed description related thereto, but it is not intended to limit the various embodiments of the present disclosure to a specific form. For example, it will be obvious to those skilled in the art to which the present disclosure pertains that the embodiments of the present disclosure may be variously modified.

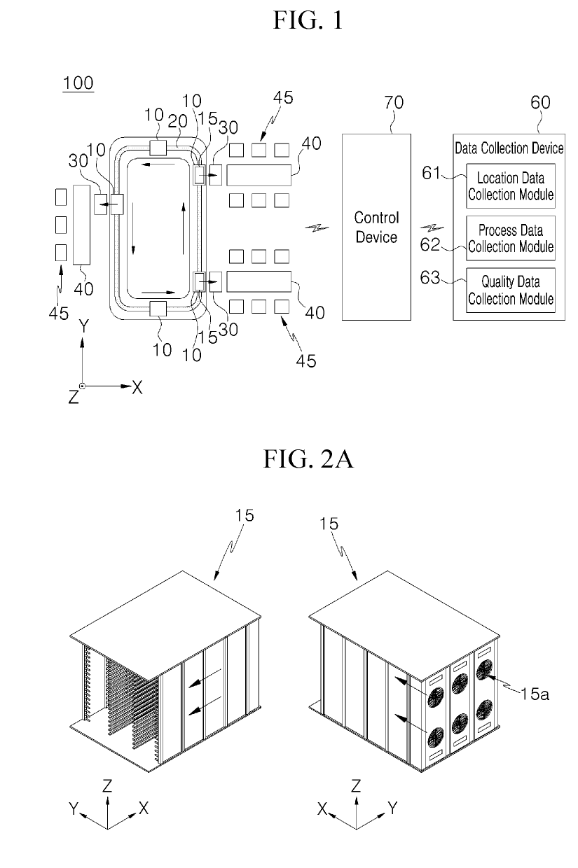

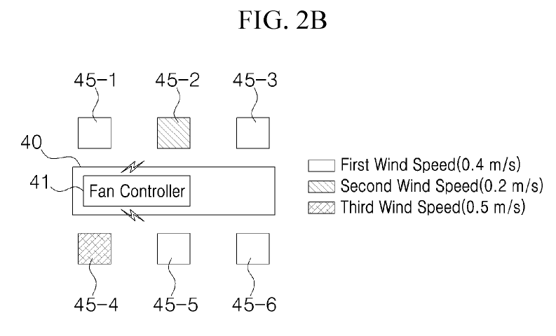

FIG. 1 is a view schematically illustrating a manufacturing automation system according to an embodiment of the present disclosure, FIG. 2A is a view illustrating the shape of a cassette according to an embodiment of the present disclosure, and FIG. 2B is a view for describing an example of varying the speed of a fan according to a process according to an embodiment of the present disclosure.

Referring to FIGS. 1 to 2B, a manufacturing automation system 100 according to an embodiment of the present disclosure may automate all or a portion of various processes for designing, manufacturing, inspecting and/or shipping a product, and variably control a process environment in consideration of characteristics of each process, thereby supporting (or enabling) high-quality product production and power savings. For example, the manufacturing automation system 100 may transfer an object to a location where a process is to be conducted, perform the corresponding process, temporarily store the target object before execution of the corresponding process, or transfer the target object that has undergone the process to a next process location, or temporarily store it. For example, the manufacturing automation system 100 according to an embodiment of the present disclosure may be widely applied to various manufacturing processes of products (e.g., display devices, semiconductors, pharmaceuticals, petrochemical products, home appliances, etc.). Hereinafter, for the convenience of description, a case in which the manufacturing automation system is used in a manufacturing process of a display device will be described as an example.

In addition, the manufacturing automation system 100 according to an embodiment of the present disclosure may variably control the process environment (e.g., wind speed, air flow, temperature, humidity, vibration, etc.) in consideration of the characteristics of each process. For example, the manufacturing automation system 100 may variably control (e.g., adjust) the wind speed of fans (e.g., equipment fan filter units (“EFUs”)) located in various process facilities (e.g., cassettes, stockers, buffer units, etc.). Hereinafter, for the convenience of description, a case where the wind speed of a fan located in the cassette is variably controlled for each process step will be described as an example.

The manufacturing automation system 100 according to an embodiment may include a transport device 10, a manufacturing line 20, a buffer unit 30, a stocker 40, a data collection device 60, and a control device 70.

The transport device 10 may transfer the target object along the manufacturing line 20. For example, the transport device 10 may transfer a cassette 15 in which a target object (e.g., a substrate included in a display device) is loaded. In the cassette 15, used items which will be used in a manufacturing process of the display device or manufactured products may loaded (or accommodated). For the convenience of description, hereinafter, a case where the substrate is loaded into the cassette 15 will be described as an example.

According to an embodiment, the cassette 15 may have a hexahedral shape, as shown in FIG. 2A, and may have a loading space formed therein in which the target object is loaded. In addition, the cassette 15 may have one surface (e.g., front surface) only open, and five surfaces (e.g., top surface, bottom surface, left-side surface, right-side surface, and the rear surface) closed. The cassette 15 may have at least one fan 15a arranged on the rear surface. The at least one fan 15a may form an airflow toward the front surface to prevent foreign substances, gases, and/or particles from flowing into the inside of the cassette 15. The wind speed of the at least one fan 15a may be variably controlled according to conditions (e.g., characteristics) of a process being performed. The operation (e.g., fan speed) of the at least one fan 15a may be wirelessly controlled by a fan controller 41, which will be described below. For example, the fan 15a may be a wireless EFU.

According to an embodiment, the transport device 10 may be an automatic guided vehicle (AGV) used in a factory automation system, an automated material handling system (AMHS), etc. However, it is not limited thereto, and various transport devices for transferring the cassette 15 may be included. For example, the transport device 10 may include an autonomous mobile robot (AMR), a rail guided vehicle (RGV), an overhead shuttle (OHS), a conveyor belt, etc.

The manufacturing line 20 may be a passage or rail along which the transport device 10 moves. According to an embodiment, when the transport device 10 is an overhead shuttle, the manufacturing line 20 may be disposed on the ceiling or an upper portion of a manufacturing space (e.g., clean-room).

The buffer unit 30 may be disposed between the transport device 10 and the stocker 40. The buffer unit 30 may temporarily store the cassette 15. For example, the buffer unit 30 may temporarily store the cassette 15 to prevent delays in processing operations due to the transfer of the cassette 15. The buffer unit 30 may include a transport member (not shown) for transferring the cassette 15 from the transport device 10 onto the buffer unit 30. For example, the buffer unit 30 may include transfer rollers (not shown) as the transport member. Specifically, when the cassette 15 reaches a location where the buffer unit 30 is located by the transport device 10, the cassette 15 may be transferred to the buffer unit 30 by the rotation of the transfer rollers. According to some embodiments, the transport member may include a transport means such as a conveyor belt or an arm.

The stocker 40 may be disposed on one side of the buffer unit 30, and may store the cassette 15. The stocker 40 may receive the cassette 15 to be processed from the buffer unit 30 and store it, or may deliver the cassette 15 that has completed the process to the buffer unit 30. According to an embodiment, the stocker 40 includes a plurality of layers in a first direction (Z-axis), wherein each layer may store a plurality of cassettes 15 in a second direction (X-axis direction) and a third direction (Y-axis direction), although it is not limited thereto.

According to an embodiment, the stocker 40 may move (or deliver) the stored cassette 15 to the corresponding process equipment 45 according to the process sequence. The stocker 40 may move (or deliver) the cassette 15 that has completed all processes to the buffer unit 30. The cassette 15, which has completed all processes and has been delivered to the buffer unit 30, may be transferred to another stocker 40 through the transport device 10.

In one embodiment, a plurality of stockers 40 may be disposed along the manufacturing line 20. Each stocker 40 may include at least one piece of process equipment 45. In some embodiments, the process equipment 45 may be disposed around the stocker 40 as a separate configuration, rather than being integrated into the stocker 40. Each process equipment 45 may perform a process on the target object (e.g., the substrate) loaded in the cassette 15. For example, each process equipment 45 may perform various manufacturing processes, such as a cell fabrication process or a module process, on the target object (e.g., the substrate).

According to an embodiment, as shown in FIG. 2B, each stocker 40 may include the fan controller 41 configured to control the operation of a fan 15a located in the cassette 15. The fan controller 41 and the fan 15a may be connected (or communicated) via wireless communication. The fan controller 41 may variably control the wind speed of the fan 15a for each process. For example, the fan controller 41, under the control of the control device 70 to be described below, may control the fan 15a of the cassette 15 to rotate at a first RPM (e.g., corresponding to a first wind speed (e.g., 0.4 meters per second (m/s)) during a first process 45-1, a third process 45-3, a fifth process 45-5, and a sixth process 45-6, control the fan 15a of the cassette 15 to rotate at a second RPM (e.g., corresponding to a second wind speed (e.g., 0.2 m/s)) during a second process 45-b, and control the fan 15a of the cassette 15 to rotate at a third RPM (e.g., corresponding to a third wind speed (e.g., 0.5 m/s)) during a fourth process 45-4. Here, each process 45-1 to 45-6 may be the process performed by corresponding process equipment 45.

The data collection device 60 may collect (or acquire) process information related to the cassette 15 in which the target object is loaded. The process information may include process step information indicating where the cassette 15 is located, location information of the cassette 15, and/or quality information related to quality associated with abnormalities of the manufacturing facility.

In one embodiment, the data collection device 60 may include a location data collection module 61, a process data collection module 62 and a quality data collection module 63.

The location data collection module 61 may collect data related to the location information of the cassette 15. For example, the location data collection module 61 may collect raw data related to the location information of the cassette 15 from a material control system (MCS) that manages the movement path of the cassette 15. In one embodiment, the location data collection module 61 may be the material control system (MCS) itself or may be included in the material control system (MCS).

The process data collection module 62 may collect data related to process step information indicating where the cassette 15 is located. For example, the process data collection module 62 may collect raw data related to the current process step in which the cassette 15 is located (in other words, raw data related to which process step is being performed in the cassette 15) from the manufacturing execution system (MES) that monitors and manages the manufacturing process. According to an embodiment, the process data collection module 62 may be the manufacturing execution system (MES) itself or may be included in the manufacturing execution system (MES).

The quality data collection module 63 may collect data related to quality information associated with abnormalities (or malfunctions) of the facility. For example, the quality data collection module 63 may collect raw data related to quality information from a fault detection and classification (FDC) system that detects abnormalities in the facility and classifies the detected abnormalities. According to an embodiment, the quality data collection module 63 may be the fault detection and classification (FDC) system itself or may be included in the fault detection and classification (FDC) system.

According to an embodiment, the data collection device 60 may acquire the process information using artificial intelligence (e.g., deep learning). For example, the data collection device 60 may include an artificial intelligence-based classification model. The artificial intelligence-based classification model may generate the process information (e.g., extract information to generate fan control information from various information included in the raw data) based on raw data collected by at least one of the location data collection module 61, the process data collection module 62, and the quality data collection module 63. The artificial intelligence-based classification model may be pre-trained using training data. In addition, the artificial intelligence-based classification model may be updated periodically or in response to a request (e.g., a user request). The control device 70 may be connected to the data collection device 60 via wired or wireless communication. The control device 70 may receive process information from the data collection device 60. The control device 70 may analyze the process information, generate fan control information to control the operation (e.g., rotation time and/or rotation intensity) of at least one fan 15a located in the cassette 15 based on the analysis results, and transmit the generated fan control information to the fan controller 41 of the stocker 40. For example, the control device 70 may analyze the collected process information to recognize which stocker among the plurality of stockers each cassette is located in, and which process step among the plurality of processes is to be performed. Thereafter, the control device 70 may determine a fan speed mapped to the recognized process step based on pre-stored mapping information, and generate fan control information for controlling the fan speed of each cassette based on the determined fan speed. Meanwhile, the control device 70 may analyze the collected process information to determine the data range to be used in generating the fan control information. For example, the control device 70 may analyze the collected process information to determine upper limit data and lower limit data to be used in generating the fan control information.

According to an embodiment, when one stocker includes a plurality of cassettes, the control device 70 may generate fan control information by mapping identification information (e.g., MAC address, cassette ID, Lot number, etc.) of each cassette to the fan speed to be applied to the corresponding fan. According to an embodiment, the control device 70 may efficiently apply drying and ventilation characteristics (e.g., the number of ventilation cycles) after completion of the process to improve the yield. For example, the control device 70 may vary the fan speed by reflecting the drying and ventilation characteristics. Specifically, in a case where the fan speed is increased to a preset value in response to an increased number of ventilation cycles, the control device 70 may variably control (e.g., maintain, increase, or decrease) the preset fan speed by reflecting the process information, in order to prevent damage to the target object due to excessively high fan speed.

According to an embodiment, the control device 70 may generate the fan control information using artificial intelligence (e.g., deep learning). For example, the control device 70 may include an artificial intelligence-based generation model. The artificial intelligence-based generation model may analyze process information and generate the fan control information based on the analyzed process information. The artificial intelligence-based generation model may be pre-trained using the training data. In addition, the artificial intelligence-based generation model may be updated periodically or in response to the request (e.g., the user request). According to an embodiment, the control device 70 may separately include an analysis model configured to analyze the process information. In this case, the generation module may receive analysis results (e.g., information about the stocker in which each cassette is located and the process step to be performed by each cassette) from the analysis model, and generate fan control information based on the received analysis result.

Meanwhile, although not shown in FIG. 1, the manufacturing automation system 100 may further include an air filter unit. According to an embodiment, the air filter unit may include a fan filter unit (FFU) or an equipment fan filter unit (EFU).

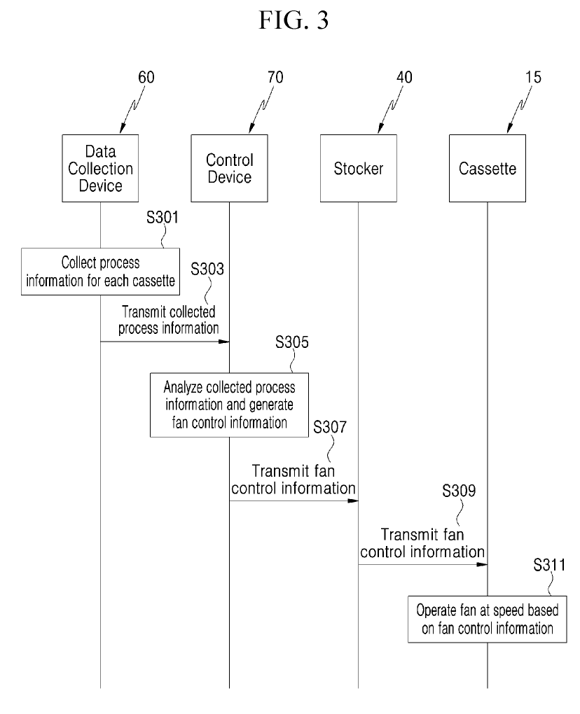

FIG. 3 is a flowchart describing a method for controlling a process environment of a manufacturing automation system according to an embodiment of the present disclosure.

Referring to FIG. 3, the method for controlling a process environment of a manufacturing automation system according to an embodiment of the present disclosure may include a step (S301) of collecting process information for each cassette during execution of the fabrication process. For example, the data collection device 60 of the manufacturing automation system 100 may acquire process step information, location information, and/or quality information for each of a plurality of cassettes. Specifically, the data collection device 60 may collect location information for each cassette 15 from a logistics control system (MCS) that manages a movement path of the cassette 15, collect process step information from a manufacturing execution system (MES) that manages a process sequence, and collect quality information from the fault detection and classification (FDC) system that detects and manages abnormalities in the target object (or manufacturing facility).

According to an embodiment, the method may include a step (S303) of transmitting the collected process information to the control device 70. For example, the data collection device 60 may transmit the collected process information to the control device 70 using various known wireless communication methods (e.g., Wi-Fi, Wi-Fi Direct, Bluetooth, Bluetooth Low Energy (BLE), Zigbee, Ultra-Wideband (UWB) communication, etc.).

According to an embodiment, the method may include a step (S305) of analyzing the collected process information and generating fan control information based on the analyzed results by the control device 70. For example, the control device 70 may analyze the collected process information to recognize which stocker among the plurality of stockers each cassette is located in, and which process step among the plurality of processes is to be performed. Thereafter, the control device 70 may determine a fan speed mapped to the recognized process step based on the pre-stored mapping information, and generate fan control information for controlling the fan speed for each cassette based on the determined fan speed. According to an embodiment, when one stocker includes a plurality of cassettes, the control device 70 may generate fan control information by mapping identification information (e.g., MAC address, cassette ID, Lot number, etc.) of each cassette to the fan speed to be applied to the corresponding fan.

According to an embodiment, the method may include a step (S307) of transmitting, by the control device 70, the generated fan control information to the fan controller 41 of the stocker 40. For example, when a first-1 cassette and a first-2 cassette are located in a first stocker and a second-1 cassette and a second-2 cassette are located in a second stocker, the control device 70 may transmit first-1 fan control information for controlling the fan speed of the first-1 cassette and first-2 fan control information for controlling the fan speed of the first-2 cassette to the fan controller of the first stocker, and transmit second-1 fan control information for controlling the fan speed of the second-1 cassette and second-2 fan control information for controlling the fan speed of the second-2 cassette to the fan controller of the second stocker. Here, the first-1 fan control information, the first-2 fan control information, the second-1 fan control information, and the second-2 fan control information may be the same or different depending on the characteristics of the process in which the first-1 cassette, the first-2 cassette, the second-1 cassette, and the second-2 cassette are located. In this way, the control device 70 may variably control the fan speed of each cassette depending on the characteristics of the process in which each cassette is located (in other words, characteristics of the process which is currently performed in the cassette).

According to an embodiment, the method may include a step (S309) of transmitting, by the fan controller 41 of the stocker 40, the fan control information to at least one fan 15a included in the corresponding cassette 15. For example, the fan controller of the first stocker may transmit the first-1 fan control information to the fan of the first-1 cassette, and transmit the first-2 fan control information to the fan of the first-2 cassette, while the fan controller of the second stocker may transmit the second-1 fan control information to the fan of the second-1 cassette, and transmit the second-2 fan control information to the fan of the second-2 cassette.

According to an embodiment, the method may include a step (S311) of operating the fan 15a of the cassette 15 at a speed based on the fan control information. For example, the fan of the first-1 cassette may operate at a first-1 speed, the fan of the first-2 cassette may operate at a first-2 speed, the fan of the second-1 cassette may operate at a second-1 speed, and the fan of the second-2 cassette may operate at a second-2 speed. Here, as described above, the first-1 speed, the first-2 speed, the second-1 speed, and the second-2 speed may all be the same, or at least one of them may be different.

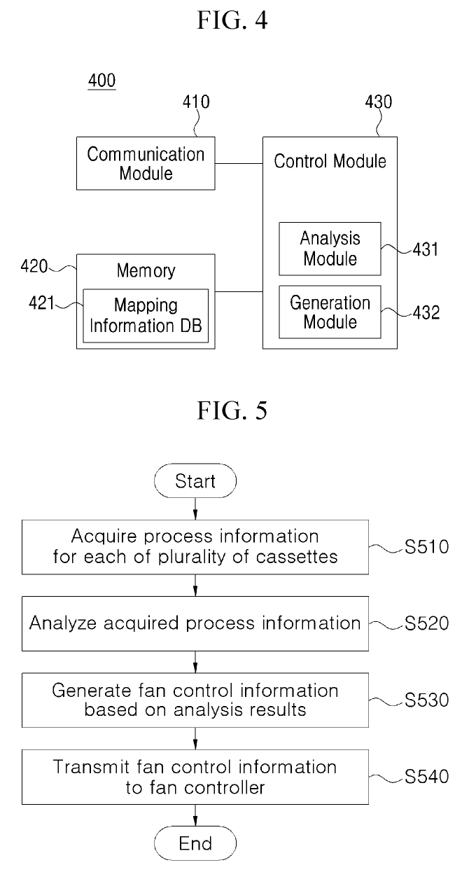

FIG. 4 is a block diagram illustrating the configuration of an electronic device according to an embodiment of the present disclosure.

Referring to FIG. 4, an electronic device 400 according to an embodiment of the present disclosure may include a communication module 410, a memory 420, and a control module 430. According to an embodiment, the electronic device 400 may correspond to the control device 70 of FIG. 1.

The communication module 410 may communicate with an external device (e.g., the data collection device 60 of FIG. 1, or the fan controller 41 of FIG. 2B). The communication module 410 may transmit and receive various types of information to and from the external device. For example, the communication module 410 may receive process information from an external device (e.g., the data collection device 60 of FIG. 1). As another example, the communication module 410 may transmit fan control information to another external device (e.g., the fan controller 41 of FIG. 2B). According to an embodiment, the communication module 410 may include a wireless communication module (e.g., a Wi-Fi module, a Bluetooth module, a low-power Bluetooth (BLE) module, a Zigbee module, or an ultra-wideband (UWB) communication module, etc.) for wireless communication with the external device. According to some embodiments, the communication module 410 may further include a wired communication module (not shown).

The memory 420 may store various data used by at least one component of the electronic device 400 (e.g., the control module 430). The data may include, for example, input data or output data for software and related commands. The memory 420 may include volatile memory (not shown) or nonvolatile memory (not shown).

According to an embodiment, the memory 420 may store a program (e.g., software) for variably controlling the manufacturing process environment. According to an embodiment, the memory 420 may store a mapping information database (DB) (421). The mapping information DB 421 may map the process characteristics to the fan speeds and store the mapping between them. For example, the mapping information DB 421 may map processes where foreign substances or contamination (e.g., inflow of foreign substances, gas, and/or particles) are less likely to occur to a relatively low speed, and map processes where contamination is more likely to occur to a relatively high fan speed. This is to save power by preventing unnecessary fan operation in processes where contamination is less likely to occur, and to improve quality by preventing contamination through high wind speed in processes where contamination is more likely to occur. The mapping information DB 421 may classify various processes into a plurality of process groups based on characteristics (e.g., chemical and gas characteristics) of the process, and may include a mapping table in which the classified process groups are mapped to fan speeds to be applied to the corresponding groups.

According to some embodiments, the mapping information DB 421 may store a mapping between the recipes (e.g., setting conditions) of the process equipment and the corresponding fan speeds. This is to vary the fan speed by reflecting the characteristics determined according to the setting conditions for performing the process even if the process equipment is the same. According to some embodiments, the mapping information DB 421 may store a mapping between the model information or lot information of the target object and the corresponding fan speeds. This is to vary the fan speed by reflecting the characteristics of the target object that differ depending on the lot.

The control module 430 may variably control the manufacturing process environment (e.g., fan speed). For example, the control module 430 may analyze process information received from an external device (e.g., the data collection device 60 of FIG. 1) through the communication module 410, generate fan control information based on the analysis results, and transmit the generated fan control information to another external device (e.g., the fan controller 41 of FIG. 2B) through the communication module 410. According to an embodiment, the control module 430 may include an analysis module 431 configured to analyze the process information and a generation module 432 configured to generate fan control information.

The analysis module 431 may analyze the collected process information to recognize which stocker among the plurality of stockers each cassette is located in, and which process step among the plurality of processes is to be performed.

The generation module 432 may determine a fan speed mapped to the recognition result based on the mapping information DB 421 stored in the memory 420, and generate fan control information for controlling the fan speed for each cassette based on the determined fan speed. According to an embodiment, when a stocker includes the plurality of cassettes, the generation module 432 may generate fan control information by mapping identification information (e.g., MAC address, cassette ID, Lot number, etc.) of each cassette to the corresponding fan speed. The generated fan control information may be transmitted to the stocker where the corresponding cassette is located, and the stocker may control the fan speed of the cassette corresponding to the identification information.

According to an embodiment, the analysis module 431 may correspond to an analysis model based on pre-trained artificial intelligence (e.g., deep learning). Additionally, the generation module 432 may correspond to a generation model based on pre-trained artificial intelligence (e.g., deep learning).

FIG. 5 is a flowchart describing a method for controlling a process environment of an electronic device according to an embodiment of the present disclosure.

Referring to FIG. 5, the method for controlling a process environment of the electronic device 400 according to an embodiment of the present disclosure may include a step (S510) of acquiring process information for each of a plurality of cassettes during execution of the fabrication process. For example, the electronic device 400 (e.g., the control module 430) may receive process step information, location information, and/or quality information for each of the plurality of cassettes from a data collection device (e.g., the data collection device 60 of FIG. 1) connected through the communication module 410. Here, the step S510 is similar to the step S303 of FIG. 3, and therefore will not be described in detail.

According to an embodiment, the method may include a step (S520) of analyzing the acquired process information. For example, the electronic device 400 (e.g., the control module 430) may analyze the collected information to recognize which stocker among the plurality of stockers each cassette is located in, and which process step among the plurality of processes is to be performed. Here, the step S520 is similar to the step S305 of FIG. 3, and therefore will not be described in detail.

According to an embodiment, the method may include a step (S530) of generating fan control information based on the analysis results. For example, the electronic device 400 (e.g., the control module 430) may determine a fan speed mapped to the recognized process step based on the mapping information DB 421 pre-stored in the memory 420, and generate fan control information for controlling the fan speed of each cassette based on the determined fan speed. Here, the step S530 is similar to the step S305 of FIG. 3, and therefore will not be described in detail.

According to an embodiment, the method may include a step (S540) of transmitting the generated fan control information to a fan controller. For example, the electronic device 400 (e.g., the control module 430) may transmit the generated fan control information to the fan controller of the corresponding stocker (e.g., the fan controller 41 of FIG. 1) through the communication module 410. Here, the step S540 is similar to the step S307 of FIG. 3, and therefore will not be described in detail. In this way, the electronic device 400 may variably control the fan speed of each cassette depending on the characteristics of the process in which each cassette is located (in other words, characteristics of the process which is currently performed in the cassette).

Meanwhile, various embodiments of the present disclosure have been described in detail above based on examples of controlling fan speed and/or operation time. However, the present disclosure may variably control the operation of various environmental control devices such as temperature, humidity, vibration, etc. depending on characteristics of the process. Through this, various embodiments of the present disclosure may improve the quality and manufacturing efficiency of the target object (e.g., the substrate) and save power.

Various embodiments of the present disclosure may improve the quality and manufacturing efficiency of the target object and save power by variably controlling the operation of an environmental control device (e.g., a fan, a temperature control device, a humidity control device, a vibration control device, etc.) depending on characteristics of the process. For example, various embodiments of the present disclosure may improve quality by preventing (or minimizing) contamination by increasing the operation time and/or operation intensity of an environmental control device in a process with a high possibility of contamination by foreign substances. In this way, various embodiments of the present disclosure may improve manufacturing efficiency (or yield) by efficiently preventing contamination (or improving quality) of the target object. As another example, various embodiments of the present disclosure may save power consumption by turning off the environmental control device or reducing the operation time and/or operation intensity in a process with no or little possibility of contamination by foreign substances.

Various embodiments of the present disclosure and the terms used herein do not limit the technical characteristics described in the present disclosure to specific embodiments, but should be interpreted to include various modifications, equivalents, or substitutions of the embodiments. With regard to the description of the drawings, similar or related components may be denoted by similar reference numerals. It is to be understood that a singular form of a noun corresponding to an item may include one or a plurality of the things, unless the relevant context clearly indicates otherwise. As used herein, each of phrases such as “A or B,” “at least one of A and B,” “at least one of A or B,” “A, B or C,” “at least one of A, B and C,” and “at least one of A, B or C” may include any one, or all possible combinations of these items enumerated together in the corresponding one of the phrases. As used herein, the terms such as “1st” and “2nd,” or “first” and “second” may be used to simply distinguish the corresponding component from another component, and does not limit the corresponding components in other aspects (e.g., an importance or order). It is to be understood that if a component (e.g., a first component) is referred to as “bonded to” or “connected to” another component (e.g., a second component), with or without the term “operatively” or “communicatively,” it means that the component may be bonded to the other component directly (e.g., by wire), wirelessly, or via a third component.

The term “module” used in various embodiments of the present disclosure may include a unit implemented in hardware, software or firmware way, and for example, may be used interchangeably with the terms such as logic, a logic block, a part, or a circuit. The module may be a part integrally formed therewith, or a minimum unit of the part or a portion thereof which performs one or more functions. For example, according to an embodiment, the module may be implemented in a form of an application-specific integrated circuit (ASIC).

Various embodiments of the present disclosure may be implemented by software (e.g., a program) including one or more instructions stored in a storage medium (e.g., an internal memory or an external memory) readable by a machine. For example, a processor of the machine (e.g., the control module 430) may call, among one or more instructions stored in the storage medium, at least one instruction, and may execute the instruction. This allows at least one function to be performed according to the called at least one instruction. The one or more instructions may include a code that is made by a compiler or a code that may be executed by an interpreter. The storage medium that may be read by a device may be provided in a form of a non-transitory storage medium. Here, the ‘non-transitory storage medium’ means that the storage medium is a tangible device and does not include a signal (e.g., an electromagnetic wave), and with regard to the term, a case, in which data are semi-permanently stored in the storage medium, and a case, in which data are temporarily stored in the storage medium, are not distinguished.

According to an embodiment, the methods according to various embodiments of the present disclosure may be provided to be included in a computer program product. The computer program product may be traded between a seller and a purchaser. The computer program product may be distributed in a form of a storage medium that may be read by a device (e.g., a compact disk read only memory (CD-ROM)) or may be distributed (e.g., downloaded or uploaded) through an application store or directly or online between two user devices. In the online distribution, at least a portion of the computer program product may be at least temporarily stored in a storage medium, such as a server of a manufacturer, a server of an application store, or a memory of a relay server, which may be read by a device, or temporarily generated.

According to various embodiments, each component or element (e.g., a module or program) of the above-described components or elements may include one or a plurality of entities, and some of the plurality of entities may be disposed to other components with being separated therefrom. According to various embodiments, among the above-described components, one or more components or operations thereof may be omitted or one or more other components or operations thereof may be added to the components. Alternatively or additionally, the plurality of components (e.g., the modules or programs) may be integrated into one component. In this case, the integrated components may perform one or more functions of each component of the plurality of components in a way that they are the same as or similar to the functions performed by the corresponding components among the plurality of components before the integration. According to various embodiments, operations performed by the modules, programs, or other components may be executed sequentially, in parallel, repeatedly, or heuristically, one or more operations may be executed in another sequence or omitted, or one or more other operations may be added thereto.

What is claimed is:

1. A manufacturing automation system comprising:
a cassette loaded with at least one target object and comprising at least one fan;
a transport device, which transfers the cassette;
a stocker, which stores the cassette transferred by the transport device, or moves the cassette to one of a plurality of pieces of process equipment, and comprising a fan controller, which controls an operation speed of the at least one fan;
a data collection device, which collects process information related to the cassette; and
a control device, which receives the collected process information, generates fan control information for variably controlling the operation speed of the at least one fan based on the received process information, and transmits the generated fan control information to the fan controller of the stocker.

2. The manufacturing automation system according to claim 1, wherein the control device is configured to analyze the process information to recognize a process step in which the cassette is located, determine a fan speed mapped to the recognized process step using a pre-stored mapping information database (DB), and generate the fan control information based on the determined fan speed.

3. The manufacturing automation system according to claim 2, wherein the mapping information DB comprises a mapping table in which process groups classified depending on characteristics of the process are mapped to fan speeds to be applied to corresponding process groups, respectively.

4. The manufacturing automation system according to claim 2, wherein the mapping information DB stores a mapping between recipes of the process equipment and corresponding fan speeds, respectively.

5. The manufacturing automation system according to claim 2, wherein the mapping information DB stores a mapping between lot information of the at least one target object and corresponding fan speeds.

6. The manufacturing automation system according to claim 1, wherein, when the cassette is provided in plurality, the control device generates the fan control information by mapping identification information for each cassette to a fan speed to be applied to the at least one fan of a corresponding cassette.

7. The manufacturing automation system according to claim 1, wherein the data collection device comprises:
a process data collection module, which collects data related to a process step in which the cassette is located;
a location data collection module, which collects data related to a location of the cassette; and
a quality data collection module, which collects data related to quality of the at least one target object.

8. The manufacturing automation system according to claim 7, wherein the data collection device comprises an artificial intelligence-based classification model which is pre-trained using training data to generate the process information based on raw data collected by at least one of the process data collection module, the location data collection module, and the quality data collection module.

9. The manufacturing automation system according to claim 1, wherein the control device comprises an artificial intelligence-based generation model which is pre-trained using training data to analyze the process information, and generate the fan control information based on the analyzed process information.

10. The manufacturing automation system according to claim 1, wherein the at least one fan and the fan controller communicate with each other via wireless communication.

11. The manufacturing automation system according to claim 1, wherein the system further comprises a buffer unit located between the transport device and the stocker, and configured to temporarily store the cassette.

12. A method for controlling a process environment of a control device comprising:
collecting process information related to a cassette loaded with at least one target object;
analyzing the collected process information;
generating fan control information for variably controlling an operation speed of at least one fan included in the cassette based on analysis results for the collected process information; and
transmitting the generated fan control information to a fan controller, which controls an operation of the at least one fan.

13. The method according to claim 12, wherein the generating of the fan control information comprises:
analyzing the process information to recognize a process step in which the cassette is located;
determining a fan speed mapped to the recognized process step using pre-stored mapping information; and
generating the fan control information based on the determined fan speed.

14. The method according to claim 12, wherein the cassette is provided in plurality, and
the generating of the fan control information comprises, when a plurality of cassettes are stored in each stocker, generating the fan control information by mapping identification information for each cassette to a fan speed to be applied to the at least one fan of a corresponding cassette.

15. The method according to claim 12, wherein the collecting of the process information comprises:
a process data collection step of collecting data related to a process step in which the cassette is located;
a position data collection step of collecting data related to a location of the cassette; and
a quality data collection step of collecting data related to quality of the at least one target object.

16. An electronic device comprising:
a communication module, which receives process information related to a cassette loaded with at least one target object; and
a control module, which analyzes the received process information, generates fan control information for variably controlling an operation speed of at least one fan included in the cassette based on analysis results for the received process information, and controls the communication module to transmit the generated fan control information to a fan controller, which controls an operation of the at least one fan.

17. The electronic device according to claim 16, further comprising a memory, which stores a mapping information database (DB) in which process groups classified depending on characteristics of the process are mapped to fan speeds to be applied to corresponding process groups.

18. The electronic device according to claim 17, wherein the control module is configured to:
analyze the process information to recognize a process step in which the cassette is located,
determine a fan speed mapped to the recognized process step using the mapping information DB, and
generate the fan control information based on the determined fan speed.

19. The electronic device according to claim 17, wherein the mapping information DB stores
a mapping between recipes of the process equipment and corresponding fan speeds, or
a mapping between lot information of the at least one target object and corresponding fan speeds.

20. The electronic device according to claim 16, wherein the cassette is provided in plurality, and, when a plurality of cassettes are stored in the stocker, the control module generates the fan control information by mapping identification information for each cassette to a fan speed to be applied to the at least one fan of a corresponding cassette.
